(19) United States
(12) Patent Application Publication
(10) Pub. No.: US 2016/0293447 A1
(43) Pub. Date: Oct. 6, 2016

(54) SUBSTRATE PROCESSING APPARATUS AND SUBSTRATE PROCESSING METHOD

(71) Applicant: SCREEN Holdings Co., Ltd., Kyoto (JP)

(72) Inventors: Akihisa IWASAKI, Kyoto (JP); Ayumi HIGUCHI, Kyoto (JP)

(21) Appl. No.: 15/085,066

(22) Filed: Mar. 30, 2016

(30) Foreign Application Priority Data
Mar. 31, 2015 (JP) 2015-071147

(51) Int. Cl. H01L 21/3213; H01L 21/67

(52) U.S. Cl. CPC H01L 21/32134; H01L 21/67051; H01L 21/67253

(57) ABSTRACT

A substrate processing apparatus (1) includes a processing part (11), a supply tank (12), and a recovery tank (13). In the supply tank (12), a processing liquid (91) circulates through a first circulation passage (211), and the temperature of the processing liquid is adjusted. The processing part performs etching processing on a substrate (9), using processing liquid from the first circulation passage. The used processing liquid is guided to the recovery tank and circulates through a second circulation passage (223). The second circulation passage includes a heater (224), a metal removal filter (231), and a metal concentration meter (233). The metal removal filter removes metal ions in the processing liquid. The metal concentration meter measures the metal ion concentration in the processing liquid, and the supply tank is replenished with appropriate processing liquid (91) from the recovery tank. This improves the utilization ratio of the processing liquid in etching processing.

### TECHNICAL FIELD

The present invention relates to a technique for performing etching processing on substrates.

### BACKGROUND ART

Processing for supplying a processing liquid to a substrate has conventionally been used when processing substrates for various applications, such as semiconductor substrates or glass substrates. Since fine circuit patterns are formed on substrates, filters for removing particles are provided in flow passages for supplying the processing liquids to the substrates. The particle removal filters are replaced or recycled on a regular basis.

For example, in the chemical solution circulating/filtering system of Japanese Patent Application Laid-Open No. 6-77207, which is used in a semiconductor element manufacturing process, clogging of a filter provided in a circulation passage is detected by a pressure gauge and a flowmeter. A causative agent of the clogging is removed by filling the filter with a solvent, and the filter is recycled. Japanese Patent Application Laid-Open No. 6-310487 discloses a batch type wet etching apparatus that uses phosphoric acid. In the wet etching apparatus, hydrofluoric acid and deionized water are supplied as a chemical solution from a chemical solution tank to a filter on a processing liquid circulation line to dissolve and remove particles adhering to the filter.

Incidentally, in recent years, costly etchants are used as the size of circuit patterns becomes smaller. For example, etchants having selectivity to materials such as titanium, tungsten, and nitrides thereof are used. Used etchants are recovered and directly used again in etching, but in order to ensure the quality of circuit patterns, the etchants are discarded every substrate processing.

However, etchants for use in the most advanced processing are very costly, and there is demand for improved utilization ratio of etchants in order to reduce the manufacturing cost of substrates. That is, there is the need to reuse etchants so that a plurality of substrates can be processed before the etchants are discarded.

### SUMMARY OF INVENTION

It is an object of the present invention to improve the utilization ratio of a processing liquid in etching processing.

A substrate processing apparatus according to a preferred embodiment of the present invention includes a processing part for supplying a processing liquid to a substrate and performing etching processing, a supply tank for storing a processing liquid; a first flow passage system in which an unused processing liquid flows between the supply tank and the processing part, a second flow passage system in which a used processing liquid flows between the processing part and the supply tank, a metal concentration meter provided in the first flow passage system or the second flow passage system and for acquiring a metal ion concentration in the processing liquid, and a metal removal filter provided in the first flow passage system or the second flow passage system and for removing metal ions in the processing liquid.

According to the present invention, the lifetime of the processing liquid can be managed while being extended in the etching processing. Consequently, the utilization ratio of the processing liquid is improved.

In one embodiment of the present invention, the first flow passage system or the second flow passage system includes a circulation passage, and a heater for adjusting a temperature of the processing liquid in the circulation passage. The metal removal filter is provided in the circulation passage, and the metal concentration meter acquires a metal ion concentration in the processing liquid in the circulation passage.

Preferably, the second flow passage system includes a recovery tank, a recovery passage for guiding the processing liquid from the processing part to the recovery tank, a replenishment passage for guiding the processing liquid from the recovery tank to the supply tank, and the circulation passage. The processing liquid circulates by flowing from and returning to the recovery tank through the circulation passage.

More preferably, the substrate processing apparatus further includes a replenishment control part for controlling replenishment of the supply tank with the processing liquid from the recovery tank on the basis of the metal ion concentration acquired by the metal concentration meter.

Preferably, the first flow passage system includes another circulation passage, and another heater for adjusting a temperature of the processing liquid in the other circulation passage. The processing liquid circulates by flowing from and returning to the supply tank through the other circulation passage. A flow rate of the processing liquid in the circulation passage per unit of time is lower than a flow rate of the processing liquid in the other circulation passage per unit of time.

More preferably, a set temperature of the processing liquid set in the heater is lower than a set temperature of the processing liquid set in the other heater.

Preferably, the circulation passage includes a main circulation passage, and a bypass flow passage having a lower flow rate per unit of time than the main circulation passage. The metal concentration meter is provided in the bypass flow passage.

More preferably, the substrate processing apparatus further includes a cooling part provided in the bypass flow passage and for reducing the temperature of the processing liquid that flows to the metal concentration meter.

Preferably, the first flow passage system or the second flow passage system further includes a parallel flow passage that is connected in parallel with the metal removal filter. The substrate processing apparatus further includes a switching part for switching between introduction of the processing liquid to the metal removal filter and introduction of the processing liquid to the parallel flow passage.

Preferably, the substrate processing apparatus further includes an air bubble removing part for removing air bubbles contained in the processing liquid, before the processing liquid flows to the metal concentration meter.

Preferably, the substrate processing apparatus further includes an acid-based chemical solution supply passage for supplying an acid-based chemical solution to the metal removal filter and removing metal ions from the metal removal filter.

Preferably, the substrate processing apparatus further includes another metal removal filter that is connected in parallel with the metal removal filter, and a switching part for switching between introduction of the processing liquid to the metal removal filter and introduction of the processing liquid to the other metal removal filter.

More preferably, the substrate processing apparatus further includes a switching control part for controlling the switching part on the basis of the metal ion concentration acquired by the metal concentration meter.

Preferably, the substrate processing apparatus further includes an acid-based chemical solution supply passage for supplying an acid-based chemical solution separately to the metal removal filter and the other metal removal filter and removing metal ions from the metal removal filter and the other metal removal filter.

Preferably, the metal concentration meter includes at least one of a spectrometer, a refractometer, and a conductivity meter.

Preferably, the metal removal filter includes a material that contains either or both of a chelate substituent and an ion exchange group.

Preferably, the substrate processing apparatus further includes a particle removal filter arranged downstream of the metal removal filter.

The present invention is also directed to a substrate processing method.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 illustrates a schematic configuration of a substrate processing apparatus;

FIG. 2 is a flowchart of basic operations of the substrate processing apparatus;

FIG. 3 is a flowchart of circulation and temperature control of a processing liquid;

FIG. 4 illustrates an overview of a change in metal concentration;

FIG. 5 illustrates another example of a part that includes a metal removal filter;

FIG. 6 illustrates an overview of a change in metal concentration;

FIG. 7 illustrates yet another example of a part that includes a metal removal filter;

FIG. 8 illustrates yet another example of a part that includes a metal removal filter;

FIG. 9 illustrates an overview of a change in metal concentration; and

FIG. 10 illustrates yet another example of a part that includes a metal removal filter.

### DESCRIPTION OF EMBODIMENTS

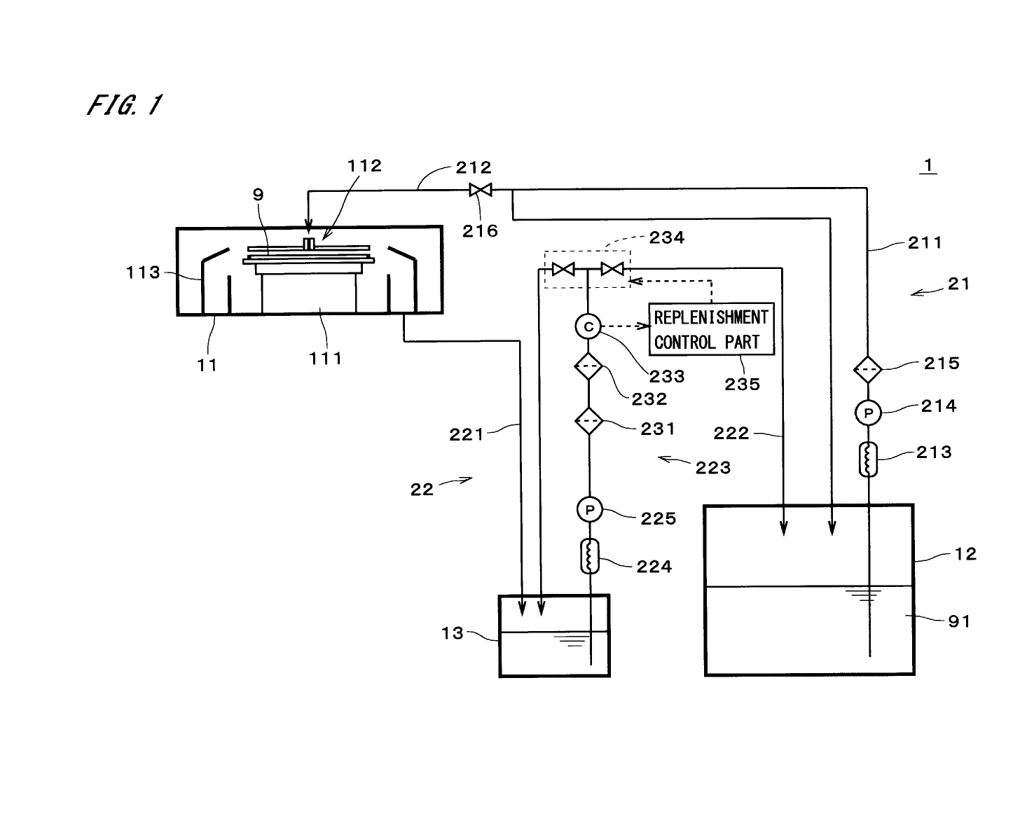

FIG. 1 illustrates a schematic configuration of a substrate processing apparatus 1 according to an embodiment of the present invention. The substrate processing apparatus 1 supplies an etchant that is a processing liquid to a substrate 9 and performs etching processing on the surface of the substrate 9. The substrate processing apparatus 1 includes a processing part 11, a supply tank 12 for storing a processing liquid 91, and a recovery tank 13 for storing a used processing liquid 91. The used processing liquid 91 is returned to the supply tank 12 from the recovery tank 13.

In the following description, a flow passage system in which an unused processing liquid 91 flows between the supply tank 12 and the processing part 11 is referred to as a “first flow passage system 21.” A flow passage system in which a used processing liquid 91 flows between the processing part 11 and the supply tank 12 is referred to as a “second flow passage system 22.” The recovery tank 13 is included in the second flow passage system 22.

The processing part 11 includes a rotation part 111 that rotates the substrate 9 in a horizontal position, a supply part 112 that supplies the processing liquid 91 to the upper surface of the substrate 9, and a liquid receiving part 113 that receives the processing liquid 91 dispersed from the substrate 9. The processing liquid 91 received by the liquid receiving part 113 and containing a high concentration of metal ions is guided to the recovery tank 13. The processing liquid 91 immediately after use contains, for example, metal ions of the order of ppm. The processing part 11 may adopt other configurations. In the present embodiment, the processing part 11 is of a single wafer type, but it may be of a batch type. The processing liquid 91 may be various etchants. The present embodiment is suitable for cases where costly etchants are used, such as etchants having excellent etch selectivity to materials such as titanium, aluminum, tungsten, other metals, and oxides or nitrides thereof, in particular, etchants for BEOL (Back End of Line).

The first flow passage system 21 includes a first circulation passage 211 and a supply passage 212. The first circulation passage 211 is provided with a heater 213, a pump 214, and a particle removal filter 215. The processing liquid 91 is circulated via the supply tank 12 through the first circulation passage 211 by the pump 214. That is, the processing liquid 91 circulates by flowing from and returning to the supply tank 12 through the first circulation passage 211. The particle removal filter 215 removes particles contained in the processing liquid 91.

The heater 213 keeps the temperature of the processing liquid 91 in the first circulation passage 211 and the supply tank 12 constant. To be precise, the heater 213, a thermometer and a temperature control part (these two are not shown) function as a temperature adjustment part, and the temperature control part controls the heater 213 on the basis of the temperature of the processing liquid 91 acquired by the thermometer. This allows the temperature of the processing liquid 91 in the first circulation passage 211 to be adjusted to a constant value.

The supply passage 212 is provided with a valve 216. The first circulation passage 211 extends to the vicinity of the processing part 11, and when the valve 216 is open, the processing liquid 91 whose temperature has been adjusted is supplied from the supply part 112 of the processing part 11 onto the substrate 9.

The second flow passage system 22 includes a recovery passage 221 for guiding the processing liquid 91 from the processing part 11 to the recovery tank 13, a replenishment passage 222 for guiding the processing liquid 91 from the recovery tank 13 to the supply tank 12, and a second circulation passage 223. In the present embodiment, the replenishment passage 222 diverges from the second circulation passage 223. The replenishment passage 222 may guide the processing liquid 91 directly from the recovery tank 13 to the supply tank 12. Part of the second circulation passage 223 may be taken as also serving as the replenishment passage 222.

The second circulation passage 223 is provided with a heater 224, a pump 225, a metal removal filter 231, a particle removal filter 232, a metal concentration meter 233, and a switching valve 234. The processing liquid 91 is circulated via the recovery tank 13 through the second circulation passage 223 by the pump 225. That is, the processing liquid 91 circulates by flowing from and returning to the recovery tank 13 through the second circulation passage 223.

The heater 224 keeps the temperature of the processing liquid 91 in the second circulation passage 223 and the recovery tank 13 constant. To be more precise, the heater 224, a thermometer and a temperature control part (these two are not shown) function as a temperature adjusting part, and the temperature control part controls the heater 224 on the basis of the temperature of the processing liquid 91 acquired by the thermometer. Thus, the temperature of the processing liquid 91 in the second circulation passage 223 is adjusted to a constant value.

The metal removal filter 231 removes metal ions, so-called dissolved metal, in the processing liquid 91. Metal ions to be removed are mainly ions of metal dissolved from the surface of the substrate 9 in the processing liquid 91 through the etching processing. The metal may contain arsenic, which has substantially metallic properties. The metal removal filter 231 includes a material that contains either or both of a chelate substituent and an ion exchange group. More specifically, a chelate resin, an ion exchange resin, or a combination of multiple types of resins is used for the metal removal filter 231.

The metal concentration meter 233 acquires the concentration of metal ions in the processing liquid 91 in the second circulation passage 223. Hereinafter, the concentration of metal ions is referred to as a “metal concentration.” More specifically, the metal concentration meter 233 includes at least one of a spectrometer, a refractometer, and a conductivity meter. Preferably, the metal concentration meter 233 includes a spectrometer. Note that the metal concentration meter 233 may be provided outside the second circulation passage 223, and the concentration of metal ions in the processing liquid 91 in the second circulation passage 223 may be acquired indirectly. For example, the metal concentration meter 233 may be provided within the recovery tank 13.

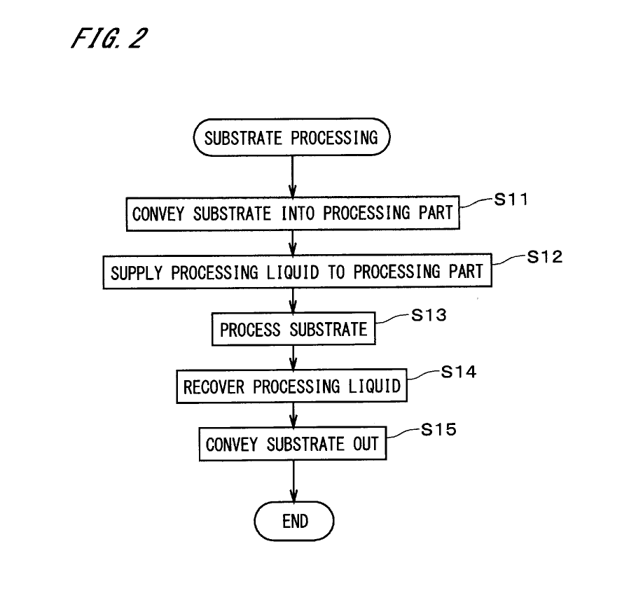

Next, basic operations of the substrate processing apparatus 1 will be described with reference to FIG. 2. First, the substrate 9 is conveyed into the processing part 11 and placed on the rotation part 111 by a transfer robot (step S11). The substrate 9 is held and rotated by the rotation part 111. The processing liquid 91 is supplied from the supply tank 12 to the processing part 11 through the supply passage 212, and supplied to the upper surface of the substrate 9 from nozzles located above the substrate 9 (step S12). In this way, etching processing is performed on the upper surface of the substrate 9 (step S13). The processing liquid 91 dispersed from the substrate 9 is received by the liquid receiving part 113 and recovered into the recovery tank 13 through the recovery passage 221 (step S14). Steps S12 to S14 are performed substantially in parallel.

Other processes such as cleaning may also be performed on the substrate 9 as necessary, and the rotation of the substrate 9 is stopped. Note that other processes may also be performed before the etching processing. The processed substrate 9 is conveyed out of the processing part 11 by the transfer robot (step S15).

In actuality, the first circulation passage 211 is connected to multiple processing parts 11, and the processing liquid 91 is supplied to each processing part 11 by opening the corresponding valve 216. These processing parts 11 are connected to a single recovery tank 13, and the used processing liquid 91 received from the processing parts 11 is recovered into the recovery tank 13.

FIG. 3 is a flowchart of the circulation and temperature control of the processing liquid 91 in the second circulation passage 223. The processing in FIG. 3 is performed in parallel with the circulation of the processing liquid 91. Although not shown in FIG. 3, the process of adjusting the temperature of the processing liquid 91 in the second circulation passage 223 and the process of removing metal ions in the processing liquid 91 flowing through the second circulation passage 223 are performed in parallel with the process of circulating the processing liquid 91, as described previously.

The metal concentration meter 233 repeatedly measures the metal concentration in the processing liquid 91 in the second circulation passage 223 (step S21), and a thermometer (not shown) also repeatedly measures the temperature of the processing liquid 91 in, the second circulation passage 223 (step S22). The acquired metal concentration and temperature are input to a replenishment control part 235 illustrated in FIG. 1. Immediately after the processing liquid 91 has been recovered from the processing part 11, the temperature of the processing liquid 91 in the recovery tank 13 may be low and the metal concentration in that processing liquid 91 may be high. However, the metal concentration does not exceed a predetermined filter threshold value while the removal capability of the metal removal filter 231 has not declined (step S25).

The replenishment control part 235 opens a valve on the second circulation passage 223 side of the switching valve 234 with a valve on the replenishment passage 222 side closed, and the processing liquid 91 circulates through the second circulation passage 223. The temperature of the processing liquid 91 is increased by the heater 224 and eventually reaches a predetermined target temperature, and the metal concentration in the processing liquid 91 is lowered by the metal removal filter 231.

When the metal concentration of the processing liquid 91 is lower than a predetermined replenishment threshold value and the processing liquid 91 has an appropriate temperature, the replenishment control part 235 determines whether it is necessary to replenish the supply tank 12 with the processing liquid 91 from the recovery tank 13 (step S23). More specifically, the supply tank 12 and the recovery tank 13 each have a level sensor for measuring a fluid level. Replenishment is performed when the amount of processing liquid 91 in the supply tank 12 falls below a replenishment starting amount and the amount of processing liquid 91 in the recovery tank 13 exceeds a replenishable amount (step S24). When it is determined that replenishment is necessary and possible, the replenishment control part 235 closes the valve on the second circulation passage 223 side of the switching valve 234 and opens the valve on the replenishment passage 222 side. Thus, the processing liquid 91 is guided from the recovery tank 13 to the supply tank 12 by the pump 225. The amount of processing liquid 91 with which the supply tank 12 is replenished may be predetermined, for example.

As described above, the replenishment control part 235 controls the replenishment of the supply tank 12 with the processing liquid from the recovery tank 13 on the basis of at least the metal ion concentration acquired by the metal concentration meter 233. Thus, the supply tank 12 is automatically replenished from the recovery tank 13 with the processing liquid 91 having an appropriate metal concentration. Moreover, the replenishment of the supply tank 12 with the processing liquid from the recovery tank 13 is controlled on the basis of the temperature of the processing liquid 91, thus also preventing a rapid drop in the temperature of the processing liquid 91 in the supply tank 12.

In the second circulation passage 223, the particle removal filter 232 is arranged downstream of the metal removal filter 231. Thus, particles that may occur in the metal removal filter 231 will be removed by the particle removal filter 232 located immediately downstream of the metal removal filter 231. This prevents particles from diffusing from the second flow passage system 22 to the first flow passage system 21.

In the metal removal filter 231, the processing liquid 91 preferably flows at a low speed in order to efficiently capture metal ions. On the other hand, the first circulation passage 211 that is connected to the supply passage 212 is required to have a certain flow rate per unit of time. Thus, if a metal removal filter is provided in the first circulation passage 211, efficient removal of metal ions may be difficult. In view of this, in the substrate processing apparatus 1, the metal removal filter 231 is provided in the second circulation passage 223. Thus, the flow rate of the processing liquid per unit of time in the second circulation passage 223 can be made lower than the flow rate of the processing liquid per unit of time in the first circulation passage 211, and metal ions can be removed efficiently. That is, the provision of the metal removal filter 231 in the second circulation passage 223 makes it possible to easily reduce the flow rate of the processing liquid 91 flowing through the metal removal filter 231, as compared with the case where the metal removal filter is provided in the first circulation passage 211.

Since the first circulation passage 211 is positioned immediately before the supply passage 212, the temperature of the processing liquid 91 in the first circulation passage 211 has to be adjusted accurately, but the temperature of the processing liquid 91 in the second circulation passage 223 does not need to be adjusted as accurately as the temperature in the first circulation passage 211. A high temperature of the processing liquid 91 may affect the measurement by the metal concentration meter 233. Thus, in the substrate processing apparatus 1, a set temperature of the processing liquid 91 set in the heater 224 in the second circulation passage 223 is lower than a set temperature of the processing liquid 91 set in the heater 213 in the first circulation passage 211. The set temperature of the processing liquid is a target temperature that is set in the temperature adjustment part including the heater, the thermometer, the temperature control part, and so on.

The ability of the metal removal filter 231 to remove metal ions eventually declines when used for a long time. As a result, the metal concentration measured in step S21 gradually increases. When the metal concentration exceeds a filter threshold value (step S25), an instruction to replace the metal removal filter 231 is given to an operator (step S26). The operator stops the operation of the substrate processing apparatus 1 and discharges the processing liquid 91 of the apparatus from the recovery tank 13. The operator cleans the flow passages with fresh deionized water and replaces the metal removal filter 231 with a new filter. Thereafter, the supply tank 12 is filled with a fresh processing liquid 91, and the circulation and temperature control of the processing liquid 91 are started.

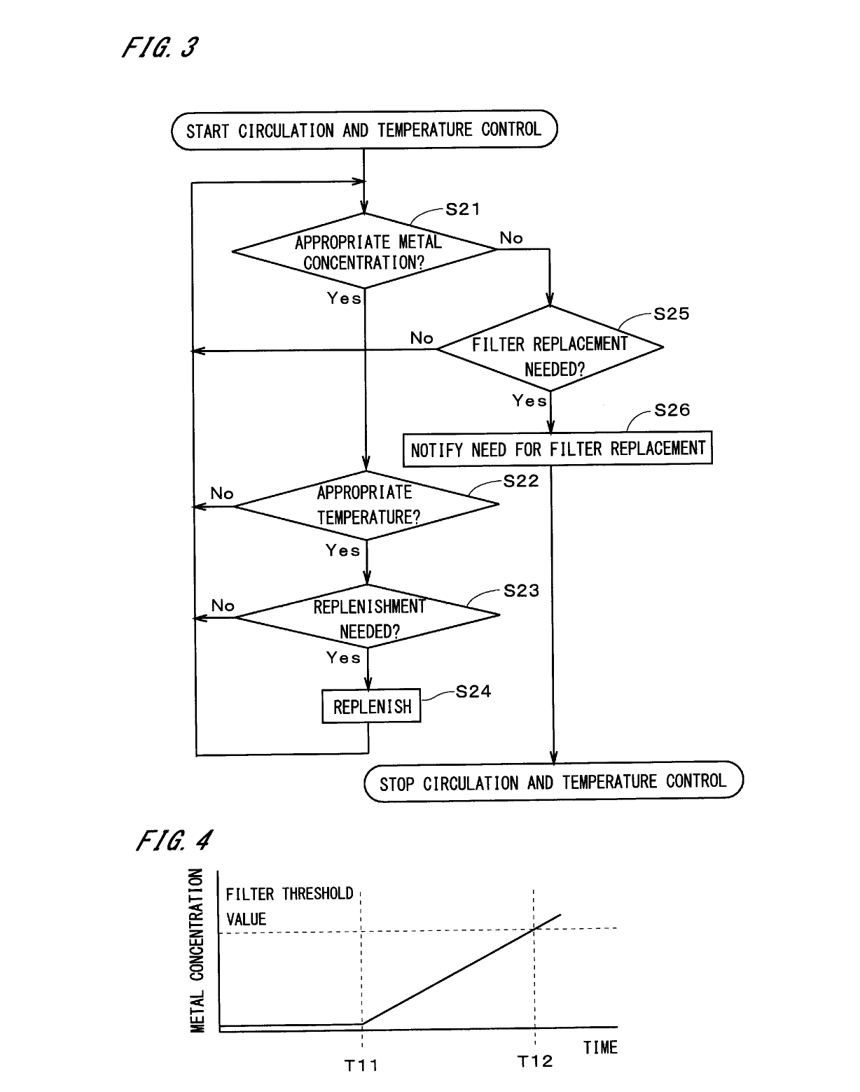

FIG. 4 illustrates an overview of the aforementioned change in the metal concentration, that is, the concentration of metal ions. The metal concentration measured by the metal concentration meter 233 is low while the metal removal filter 231 has the ability to remove metal ions. In actuality, the metal concentration varies to some extent whenever the used processing liquid 91 flows from the processing part 11 into the recovery tank 13. When the metal removal filter 231 becomes saturated at time T11 and the ability to remove metal ions decreases, the metal concentration gradually increases. When the metal concentration exceeds the filter threshold value at time T12, the need for filter replacement is notified to the operator.

In the substrate processing apparatus 1, providing not only the metal removal filter 231 but also the metal concentration meter 233 enables the lifetime of the processing liquid 91 to be managed while being extended. As a result, the utilization ratio of the processing liquid 91 can be improved while preventing the effects of the degradation of chemical solution properties such as etch selectivity. In other words, the costly processing liquid 91 can be used without waste while being recycled, thus reducing the manufacturing cost of the substrate 9.

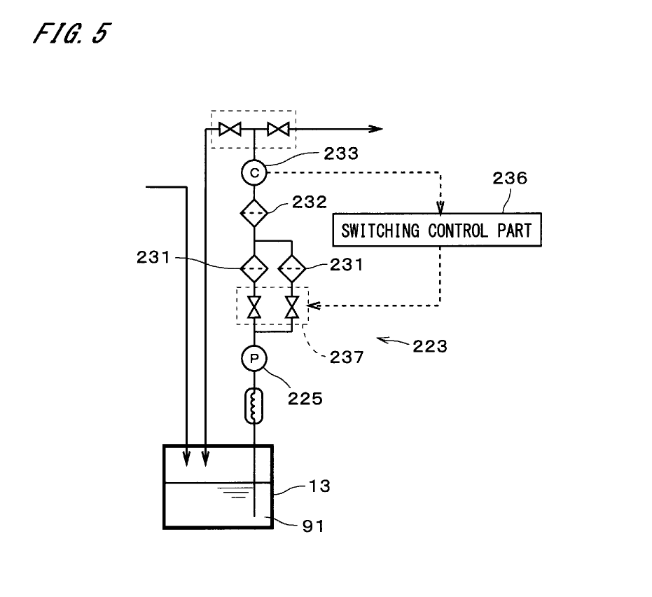

FIG. 5 illustrates another example of a part of the substrate processing apparatus 1 that includes the metal removal filter 231. In FIG. 5, two metal removal filters 231 are provided. A switching valve 237 is provided between the metal removal filters 231 and the pump 225. The switching valve 237 is controlled by a switching control part 236, and the metal concentration from the metal concentration meter 233 is input to the switching control part 236. The other configuration of the substrate processing apparatus 1 is the same as the configuration in FIG. 1, and the same reference numerals are used. Hereinafter, when there is a need to distinguish between the two metal removal filters 231 in FIG. 5, one of the metal removal filters 231 is referred to as a “first metal removal filter 231,” and the other is referred to as a “second metal removal filter 231.” The first metal removal filter 231 and the second metal removal filter 231 are connected in parallel. The switching valve 237 functions as a switching part for switching between introduction of the processing liquid 91 to the first metal removal filter 231 and introduction of the processing liquid 91 to the second metal removal filter 231.

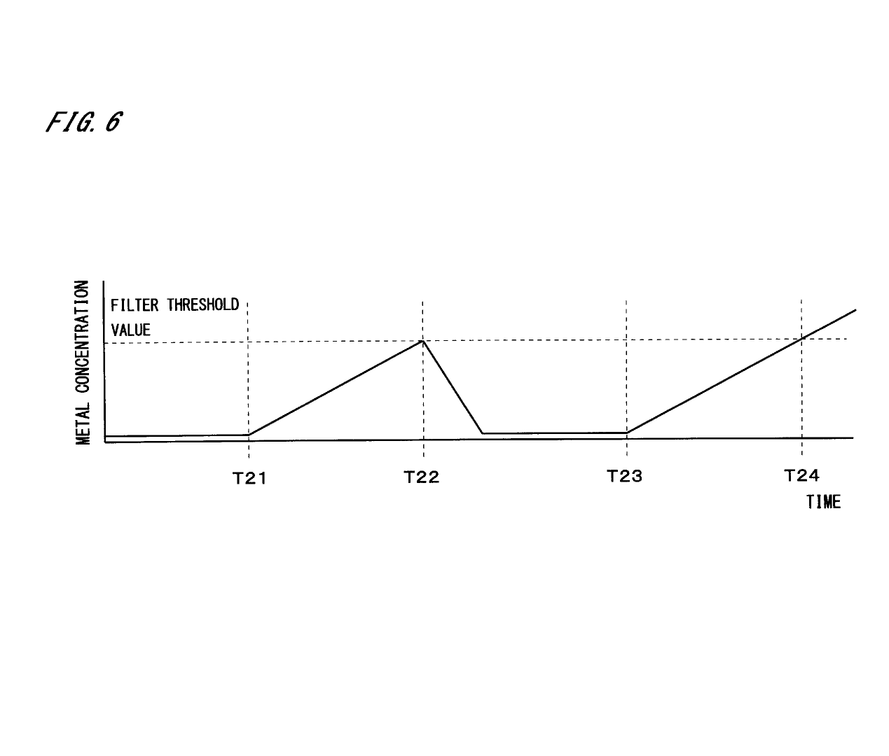

FIG. 6 illustrates an overview of the output from the metal concentration meter 233 when the configuration in FIG. 5 is adopted. First, the switching valve 237 causes the processing liquid 91 to pass through the first metal removal filter 231 and does not guide the processing liquid 91 to the second metal removal filter 231. Thus, as in the case of FIG. 4, the metal concentration remains low while the first metal removal filter 231 exhibits the ability to remove metal ions. When the ability of the first metal removal filter 231 to remove metal ions starts decreasing at time T21, the metal concentration gradually increases.

When the metal concentration exceeds the filter threshold value at time T22, the switching control part 236 controls the switching valve 237 to allow passage of the processing liquid 91 through the second metal removal filter 231 and to not guide the processing liquid 91 to the first metal removal filter 231. Thus, the metal concentration gradually decreases. When the second metal removal filter 231 becomes saturated at time T23 and the ability to remove metal ions decreases, the metal concentration gradually increases. When the metal concentration exceeds the filter threshold value at time T24, the need for filter replacement is notified to the operator.

Using the two metal removal filters 231 in turn enables the continuous operating time of the substrate processing apparatus 1 to be extended. In addition, the filters to be used can be switched automatically by the switching control part 236 controlling the switching valve 237 on the basis of the metal concentration acquired by the metal concentration meter 233.

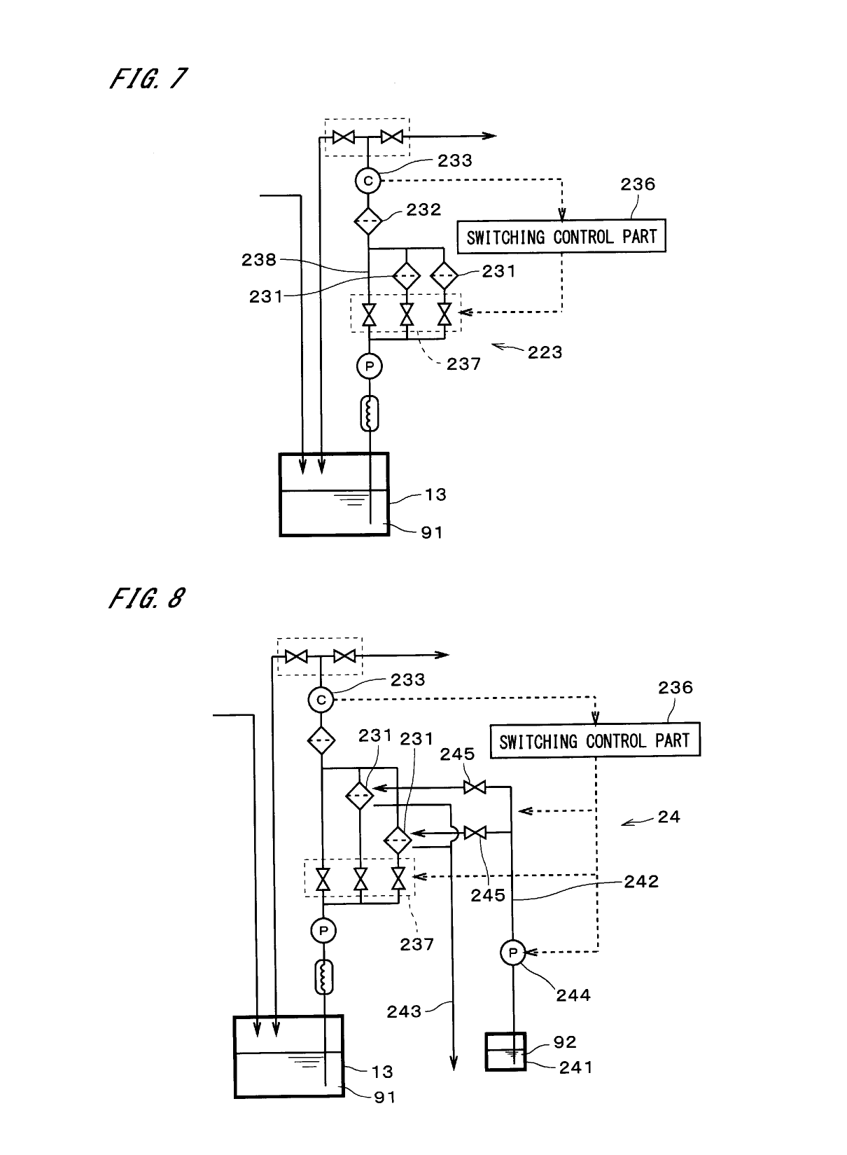

FIG. 7 illustrates yet another example of a part of the substrate processing apparatus 1 that includes the metal removal filter 231. In FIG. 7, the second circulation passage 223 includes a parallel flow passage 238 that is connected in parallel with the two metal removal filters 231 in FIG. 5. A switching valve 237 is controlled by the switching control part 236. The other configuration of the substrate processing apparatus 1 is the same as the configuration in FIG. 5, and the same reference numerals are used. The switching valve 237 functions as a switching part for switching of introduction of the processing liquid 91 to the first metal removal filter 231, introduction of the processing liquid 91 to the second metal removal filter 231, and introduction of the processing liquid 91 to the parallel flow passage 238.

Under the control of the switching control part 236, the processing liquid 91 flows into the parallel flow passage 238 and does not flow to either of the metal removal filters 231, in the case where the metal concentration in the processing liquid 91 stored in the recovery tank 13 is low, or in the case of performing processing that does not greatly increase the metal concentration in the processing liquid 91. This prevents the processing liquid 91 from passing through the metal removal filters 231 more than necessary. As a result, the lifetimes of the metal removal filters 231 can be extended.

The operation performed by the switching control part 236 when switching the filters to be used is the same as that in FIG. 5, except in the provision of the parallel flow passage 238. The parallel flow passage 238 may also be provided in the case of a single metal removal filter 231 as in FIG. 1.

FIG. 8 illustrates an example in which an acid-based chemical solution supply part 24 is further added to the configuration in FIG. 7. The acid-based chemical solution supply part 24 includes a chemical solution tank 241, an acid-based chemical solution supply passage 242, an acid-based chemical solution discharge passage 243, a pump 244, and two valves 245. The chemical solution tank 241 stores an acid-based chemical solution 92. The pump 244 is provided in the acid-based chemical solution supply part 24. The acid-based chemical solution supply passage 242 diverges into two passages partway along the passage and communicates the chemical solution tank 241 with the two metal removal filters 231. The two valves 245 are each provided between a different one of the two metal removal filters 231 and the pump 244 in the acid-based chemical solution supply passage 242. Thus, the acid-based chemical solution supply part 24 is capable of supplying the acid-based chemical solution 92 separately to the two metal removal filters 231 through the acid-based chemical solution supply passage 242. The acid-based chemical solution discharge passage 243 discharges the acid-based chemical solution 92 from each of the metal removal filters 231 to the outside.

Examples of the acid-based chemical solution 92 to be used include hydrochloric acid, sulfuric acid, hydrofluoric acid, phosphoric acid, and nitric acid. By supplying the acid-based chemical solution 92 to the metal removal filters 231, metal ions are removed from the metal removal filters 231. The metal removal filters 231 are thus recycled, and this further extends the lifetimes of the metal removal filters 231.

The acid-based chemical solution supply part 24 may also be provided in the case of a single metal removal filter 231 as in FIG. 1, but is in particular suitable for cases where two or more metal removal filters 231 are provided as in FIG. 8.

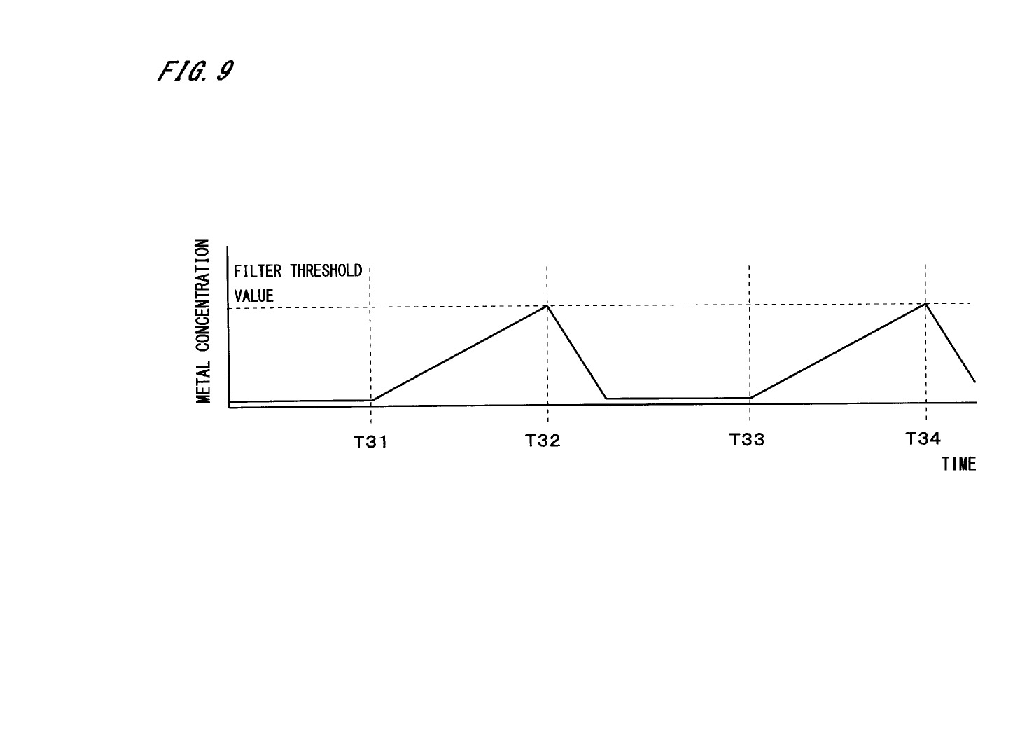

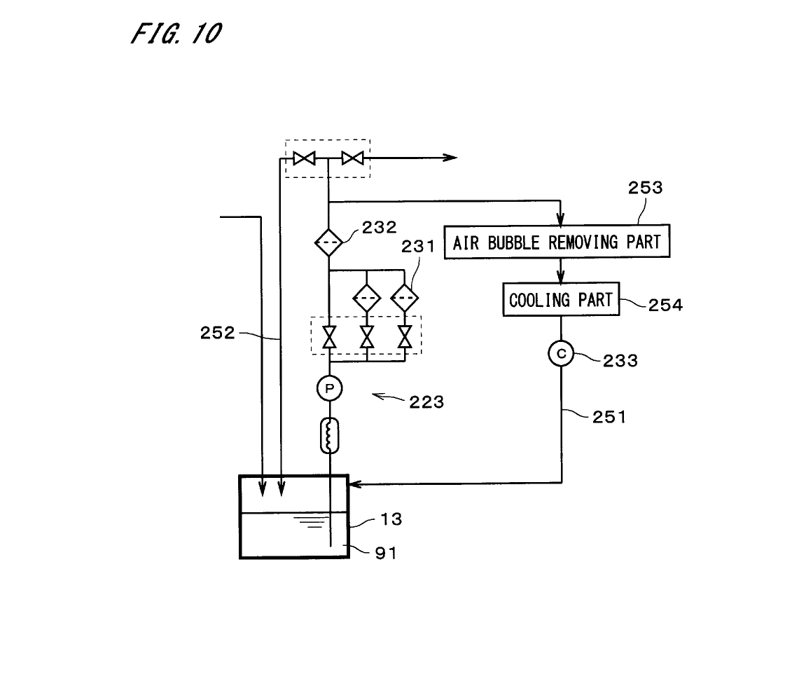

FIG. 9 illustrates an overview of the output from the metal concentration meter 233 when the configuration in FIG. 8 is adopted. First, the switching valve 237 causes the processing liquid 91 to pass through the first metal removal filter 231 and does not guide the processing liquid 91 to the second metal removal filter 231. Thus, the metal concentration remains low while the first metal removal filter 231 exhibits the ability to remove metal ions. When the first metal removal filter 231 becomes saturated at time T31 and the ability to remove metal ions decreases, the metal concentration gradually increases.

When the metal concentration exceeds the filter threshold value at time T32, the switching control part 236 controls the switching valve 237 to allow passage of the processing liquid 91 through the second metal removal filter 231 and to not guide the processing liquid 91 to the first metal removal filter 231. Thus, the metal concentration gradually decreases. In parallel with this, the acid-based chemical solution supply part 24 supplies the acid-based chemical solution 92 to the first metal removal filter 231 and recycles the first metal removal filter 231.

When the second metal removal filter 231 becomes saturated at time T33 and the ability to remove metal ions decreases, the metal concentration gradually increases. When the metal concentration exceeds the filter threshold value at time T34, the switching control part 236 controls the switching valve 237 to allow passage of the processing liquid 91 through the first metal removal filter 231 and to not guide the processing liquid 91 to the second metal removal filter 231. Thus, the metal concentration gradually decreases. In parallel with this, the acid-based chemical solution supply part 24 supplies the acid-based chemical solution 92 to the second metal removal filter 231 and recycles the second metal removal filter 231.

Thereafter, the metal removal filters 231 are recycled while not being used, and the two metal removal filters 231 are used alternately. This extends the continuous operating time of the substrate processing apparatus 1. Although not shown, the switching control part 236 controls not only the switching valve 237 but also the acid-based chemical solution supply part 24 on the basis of the metal concentration acquired by the metal concentration meter 233.

FIG. 10 illustrates an example in which a bypass flow passage 251 is provided in the configuration in FIG. 7. The bypass flow passage 251 guides the processing liquid 91 from the downstream side of the particle removal filter 232 to the recovery tank 13. When a main flow passage of the second circulation passage 223 other than the bypass flow passage 251 is referred to as a “main circulation passage 252,” the bypass flow passage 251 has a lower flow rate per unit of time than the main circulation passage 252.

The metal concentration meter 233 is provided in the bypass flow passage 25. This allows a small amount of processing liquid 91 to be guided to the metal concentration meter 233, increasing the degree of freedom in the arrangement of the metal concentration meter 233.

The bypass flow passage 251 includes a cooling part 254 and an air bubble removing part 253 in this order on the upstream side of the metal concentration meter 233. The air bubble removing part 253 removes air bubbles contained in the processing liquid 91, before the processing liquid 91 flows to the metal concentration meter 233. This prevents air bubbles from entering the metal concentration meter 233 and deteriorating the accuracy of measurement. The cooling part 254 lowers the temperature of the processing liquid 91 flowing to the metal concentration meter 233. This prevents high-temperature processing liquid 91 from affecting the metal concentration meter 233. As described previously, the flow rate of the processing liquid 91 flowing through the bypass flow passage 251 is lower than the flow rate of the processing liquid 91 flowing through the main circulation passage 252. Thus, the cooling part 254 has little influence on the temperature of the processing liquid 91 in the recovery tank 13.

The substrate processing apparatus 1 may be modified in various ways.

In FIGS. 5 and 7, for example, three or more metal removal filters 231 may be connected in parallel. The metal removal filters 231 to be used may be switched through an operation by the operator.

In the case where gravity can be used to replenish the supply tank 12 with the processing liquid 91 from the recovery tank 13, a replenishment passage 222 with no pumps may be provided between the recovery tank 13 and the supply tank 12.

The temperature control function may be omitted from the second circulation passage 223. In this case, after the supply tank 12 is replenished with the processing liquid 91, temperature adjustment is performed while the processing liquid 91 is not supplied to the processing part 11, until the processing liquid 91 in the supply tank 12 and the first circulation passage 211 reaches an appropriate temperature. The replenishment of the supply tank 12 with the processing liquid 91 from the recovery tank 13 may be implemented through an operation by the operator. The recycling of the metal removal filters 231 through the supply of the acid-based chemical solution to the metal removal filters 231 may also be implemented through an operation by the operator.

The metal removal filters 231 and the metal concentration meter 233 may be provided in the first flow passage system 21. In this case, the metal removal filter 231 and the metal concentration meter 233 are preferably provided in the first circulation passage 211. The metal removal filters 231, the parallel flow passage 238, and the acid-based chemical solution supply part 24 in the various aforementioned layouts, for example, may also be provided in the first flow passage system 21. In this case, the recovery tank 13 may be omitted.

The metal removal filters 231 and the metal concentration meter 233, for example, may be provided at positions other than in the second circulation passage 223 of the second flow passage system 22. In other words, the metal removal filters 231 and the metal concentration meter 233 may be provided at various positions in the first flow passage system 21 and the second flow passage system 22. Wherever the metal removal filters 231 are provided, it is preferable for the particle removal filter 232 to be provided downstream of the metal removal filters 231.

The air bubble removing part 253 and the cooling part 254 may be provided upstream of the metal concentration meter 233 in an example in which the bypass flow passage 251 is not provided. The bypass flow passage 251 may also be provided in the first circulation passage 211 of the first flow passage system 21, and the metal removal filters 231 and/or the metal concentration meter 233 may be provided therein.

The configurations of the preferred embodiments and variations described above may be appropriately combined as long as there are no mutual inconsistencies.

While the invention has been shown and described in detail, the foregoing description is in all aspects illustrative and not restrictive. It is therefore to be understood that numerous modifications and variations can be devised without departing from the scope of the invention. This application claims priority benefit under 35 U.S.C. Section 119 of Japanese Patent Application No. 2015-071147 filed in the Japan Patent Office on May 31, 2015, the entire disclosure of which is incorporated herein by reference.

### REFERENCE SIGNS LIST

1 Substrate processing apparatus
9 Substrate
11 Processing part
12 Supply tank
13 Recovery tank
21 First flow passage system
22 Second flow passage system
91 Processing liquid
92 Acid-based chemical solution
211 First circulation passage
213 Heater
221 Recovery passage
222 Replenishment passage
223 Second circulation passage
224 Heater
231 Metal removal filter
232 Particle removal filter
233 Metal concentration meter
235 Replenishment control part
236 Switching control part
237 Switching valve (switching part)
238 Parallel flow passage
242 Acid-based chemical solution supply passage
251 Bypass flow passage
252 Main circulation passage
253 Air bubble removing part
254 Cooling part
S11 to S15, S21 to S26 Step

1. A substrate processing apparatus comprising:
a processing part for supplying a processing liquid to a substrate and performing etching processing;
a supply tank for storing a processing liquid;
a first flow passage system in which an unused processing liquid flows between said supply tank and said processing part;
a second flow passage system in which a used processing liquid flows between said processing part and said supply tank;
a metal concentration meter provided in said first flow passage system or said second flow passage system and for acquiring a metal ion concentration in the processing liquid; and
a metal removal filter provided in said first flow passage system or said second flow passage system and for removing metal ions in the processing liquid.

2. The substrate processing apparatus according to claim 1, wherein
said first flow passage system or said second flow passage system includes:
a circulation passage; and
a heater for adjusting a temperature of the processing liquid in said circulation passage,
said metal removal filter is provided in said circulation passage, and
said metal concentration meter acquires a metal ion concentration in the processing liquid in said circulation passage.

3. The substrate processing apparatus according to claim 2, wherein
said second flow passage system includes:
a recovery tank;
a recovery passage for guiding the processing liquid from said processing part to said recovery tank;
a replenishment passage for guiding the processing liquid from said recovery tank to said supply tank; and
said circulation passage, and
the processing liquid circulates by flowing from and returning to said recovery tank through said circulation passage.

4. The substrate processing apparatus according to claim 3, further comprising:
a replenishment control part for controlling replenishment of said supply tank with the processing liquid from said recovery tank on the basis of the metal ion concentration acquired by said metal concentration meter.

5. The substrate processing apparatus according to claim 3, wherein
said first flow passage system includes:
another circulation passage; and
another heater for adjusting a temperature of the processing liquid in said another circulation passage,
the processing liquid circulates by flowing from and returning to said supply tank through said another circulation passage, and
a flow rate of the processing liquid in said circulation passage per unit of time is lower than a flow rate of the processing liquid in said another circulation passage per unit of time.

6. The substrate processing apparatus according to claim 5, wherein
a set temperature of the processing liquid set in said heater is lower than a set temperature of the processing liquid set in said another heater.

7. The substrate processing apparatus according to claim 2, wherein
said circulation passage includes:
a main circulation passage; and
a bypass flow passage having a lower flow rate per unit of time than said main circulation passage, and
said metal concentration meter is provided in said bypass flow passage.

8. The substrate processing apparatus according to claim 7, further comprising:
a cooling part provided in said bypass flow passage and for reducing the temperature of the processing liquid that flows to said metal concentration meter.

9. The substrate processing apparatus according to claim 1, wherein
said first flow passage system or said second flow passage system further includes a parallel flow passage that is connected in parallel with said metal removal filter,
said substrate processing apparatus further comprising:
a switching part for switching between introduction of the processing liquid to said metal removal filter and introduction of the processing liquid to said parallel flow passage.

10. The substrate processing apparatus according to claim 1, further comprising:
an air bubble removing part for removing air bubbles contained in the processing liquid, before the processing liquid flows to said metal concentration meter.

11. The substrate processing apparatus according to claim 1, further comprising:
an acid-based chemical solution supply passage for supplying an acid-based chemical solution to said metal removal filter and removing metal ions from said metal removal filter.

12. The substrate processing apparatus according to claim 1, further comprising:
another metal removal filter that is connected in parallel with said metal removal filter; and
a switching part for switching between introduction of the processing liquid to said metal removal filter and introduction of the processing liquid to said another metal removal filter.

13. The substrate processing apparatus according to claim 12, further comprising:
a switching control part for controlling said switching part on the basis of the metal ion concentration acquired by said metal concentration meter.

14. The substrate processing apparatus according to claim 12, further comprising:
an acid-based chemical solution supply passage for supplying an acid-based chemical solution separately to said metal removal filter and said another metal removal filter and removing metal ions from said metal removal filter and said another metal removal filter.

15. The substrate processing apparatus according to claim 1, wherein
said metal concentration meter includes at least one of a spectrometer, a refractometer, and a conductivity meter.

16. The substrate processing apparatus according to claim 1, wherein
said metal removal filter includes a material that contains either or both of a chelate substituent and an ion exchange group.

17. The substrate processing apparatus according to claim 1, further comprising:
a particle removal filter arranged downstream of said metal removal filter.

18. A substrate processing method comprising:
a) supplying a processing liquid from a supply tank to a processing part;
b) supplying said processing liquid to a substrate and performing etching processing in said processing part; and
c) recovering said processing liquid from said processing part into a recovery tank,
the substrate processing method further comprising:
d) circulating a processing liquid by causing the processing liquid to flow from and return to said recovery tank through a circulation passage;
e) during said operation d), adjusting a temperature of said processing liquid in said circulation passage;
f) during said operation d), removing metal ions in said processing liquid flowing through said circulation passage;
g) during said operation d), acquiring a metal ion concentration in said processing liquid; and
h) replenishing said supply tank with said processing liquid from said recovery tank on the basis of the metal ion concentration acquired in said operation g).
